(19) United States
(12) Patent Application Publication
(10) Pub. No.: US 2012/0107606 A1
(43) Pub. Date: May 3, 2012

(54) ARTICLE MADE OF ALUMINUM OR ALUMINUM ALLOY AND METHOD FOR MANUFACTURING

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); MAN-XI ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/180,711

(22) Filed: Jul. 12, 2011

(30) Foreign Application Priority Data
Oct. 28, 2010 (CN) 201010523201.1

(51) Int. Cl. B32B 15/04; B05D 1/36; C23C 14/06; B05D 5/00; B32B 18/00; C23C 14/35

(52) U.S. Cl. 428/336; 428/457; 428/448; 428/472.2; 428/422; 204/192.22; 204/192.23; 204/192.15; 427/58; 427/126.2; 427/126.4; 427/126.1

(57) ABSTRACT

An article includes a substrate made of aluminum or aluminum alloy, an insulating coating formed on the substrate, and an anticorrosive coating formed on the insulating coating. The insulating coating is composed of electrically insulating ceramic material or polymer. The anticorrosive coating is a ceramic coating formed by physical vapor deposition.

### BACKGROUND

1. Technical Field

The disclosure generally relates to articles made of aluminum or aluminum alloy and method for manufacturing the articles.

2. Description of Related Art

Due to having many good properties such as light weight and quick heat dissipation, aluminum and aluminum alloy are widely used in manufacturing components (such as housings) of electronic devices. However, aluminum and aluminum alloy have a relatively low erosion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary article made of aluminum or aluminum alloy and method for manufacturing the article. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of an article.

FIG. 2 is a schematic view of a magnetron sputtering machine for manufacturing the article in FIG. 1.

### DETAILED DESCRIPTION

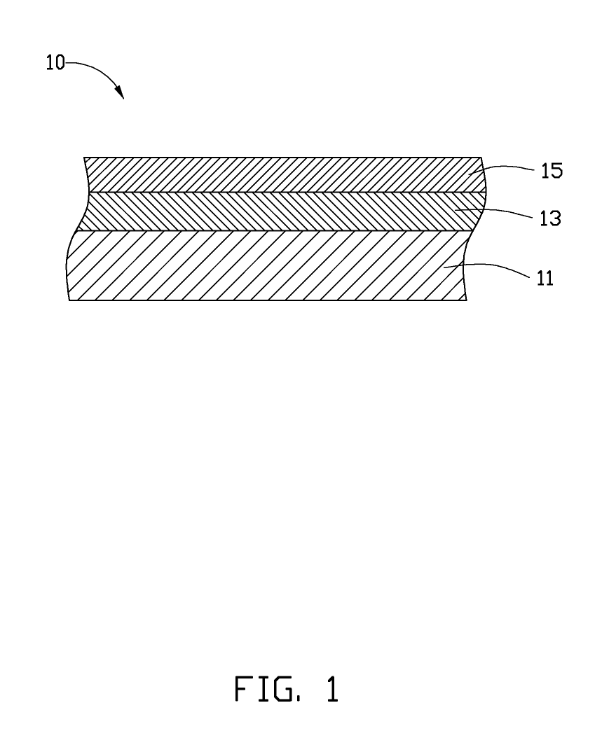

FIG. 1 shows a cross-section of an exemplary article 10 made of aluminum or aluminum alloy. The article 10 may be a housing for electronic devices, such as mobile phones. In addition, the article may be the frames for glasses, parts of architecture, or components for vehicles. The article 10 includes a substrate 11 made of aluminum or aluminum alloy, an insulating coating 13, and an anticorrosive coating 15.

The insulating coating 13 is directly formed on a surface of the substrate 11. The insulating coating 13 is electrically insulating and may be composed of an insulating ceramic material, such as silicon oxide and aluminum oxide. In this exemplary embodiment, the insulating coating 13 is composed of silicon oxide. In the embodiment, the insulating coating 13 has a light color, such as silver, white, or gray, so it does not interfere with the color of the anticorrosive coating 15. The thickness of the insulating coating 13 may be from about 2.0 μm to about 3.0 μm.

The anticorrosive coating 15 is directly formed on the insulating coating 13. The anticorrosive coating 15 is a ceramic coating. The anticorrosive coating 15 may be composed of one ceramic material selected from the group consisting of TiN, TiON, TiCN, CrN, CrON, and CrCN. In this exemplary embodiment, the anticorrosive coating 15 is composed of TiN. The thickness of the anticorrosive coating 15 may be from about 0.5 μm to about 3.0 μm.

The insulating coating 13 and the anticorrosive coating 15 may be formed by physical vapor deposition (PVD), such as magnetron sputtering, or arc ion plating.

The insulating coating 13 set between the substrate 11 and the anticorrosive coating 15 is electrically insulating. When the article 10 is placed in a corrosive condition, the insulating coating 13 separates the substrate 11 from the anticorrosive coating 15, thereby the substrate 11 and the anticorrosive coating 15 cannot form the cathode and anode required by electrochemical corrosion. Thus, the corrosion resistance of the article 10 can be improved.

An exemplary process manufacturing the article 10 may include the following steps.

Referring to FIG. 1, a substrate 11 is provided. The substrate 11 is made of aluminum or aluminum alloy.

The substrate 11 is pretreated. For example, the substrate 11 is ground and electrolytic polished to produce a smooth surface. The substrate 11 is cleaned with a solution (e.g., alcohol or acetone) in an ultrasonic cleaner, to remove impurities such as grease or dirt from the substrate 11. Then, the substrate 11 is dried.

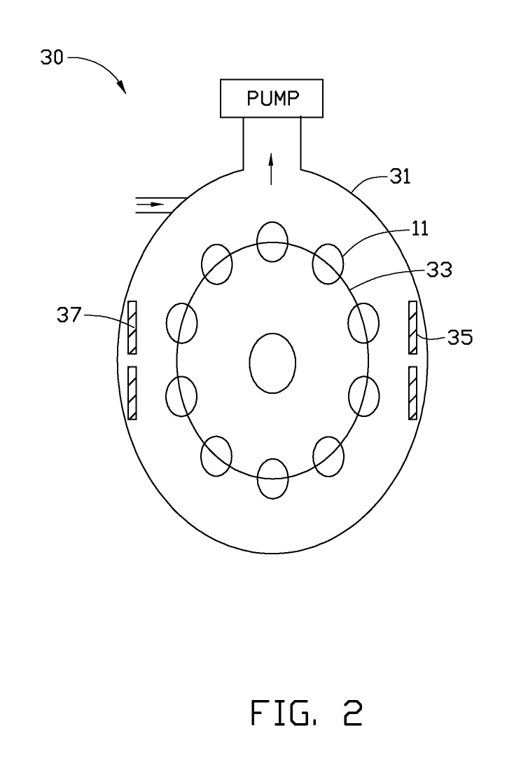

The insulating coating 13 is directly formed on the substrate 11 by a PVD method, such as magnetron sputtering and arc ion plating. In this exemplary embodiment, the insulating coating 13 is formed by magnetron sputtering. Before depositing the insulating coating 13, the substrate 11 is cleaned by argon plasma cleaning. The substrate 11 is hold on a rotating bracket 33 in a vacuum chamber 31 of a magnetron sputtering machine 30 as shown in FIG. 2. The vacuum chamber 31 is evacuated to maintain an internal pressure of about 5×10⁻³ Pa to about 8×10⁻³ Pa. Pure argon is fed into the vacuum chamber 31 at a flux of about 250 Standard Cubic Centimeters per Minute (sccm) to about 500 sccm, to generate plasma. A bias voltage of about −300 volts (V) to about −800 V is applied to the substrate 11 for about 3 min to about 10 min. The substrate 11 is washed by argon plasma to further remove any grease or dirt. Thus, the binding force between the substrate 11 and the insulating coating 13 is enhanced.

Once the argon plasma cleaning is finished, argon and oxygen are simultaneously fed into the vacuum chamber 31, with the argon as a sputtering gas, and the oxygen as a reactive gas. The flux of the argon supplied into the vacuum chamber 31 is adjusted to be about 150 sccm to about 300 sccm. The flux of the oxygen is about 50 sccm to about 200 sccm. The temperature in the vacuum chamber 31 is maintained at about 50° C. to about 150° C. A bias voltage is applied to the substrate 11 in a range of about −50 V to about −300 V. First targets 35 made of aluminum or silicon are evaporated at an electric power of about 5 kW to about 13 kW, depositing the insulating coating 13 on the substrate 11. Deposition of the insulating coating 13 may take about 30 min to about 120 min. The electric power may be a medium-frequency AC power, with a duty cycle of about 30% to about 70%.

The anticorrosive coating 15 is then formed on the insulating coating 13 by a PVD method, such as magnetron sputtering and arc ion plating. In this exemplary embodiment, the anticorrosive coating 15 is formed by magnetron sputtering. This step may be carried out in the same magnetron sputtering machine 30. When the anticorrosive coating 15 is composed of TiN or CrN, this step can be carried out as the following steps.

The first targets 35 are switched off. The temperature inside the vacuum chamber 31 is maintained at about 50° C. to about 150° C. Argon and nitrogen are simultaneously supplied into the vacuum chamber 31, with the argon as a sputtering gas, and the nitrogen as a reactive gas. The flux of argon is in a range of about 150 sccm to about 300 sccm. The flux of nitrogen is about 10 sccm to about 120 sccm. A bias voltage is applied to the substrate 11 in a range of about −50 V to about −300 V. Second targets 37 made of titanium or chromium are evaporated at an electric power of about 5 kW to about 10 kW, depositing the anticorrosive coating 15 in the form of a TiN layer on the insulating coating 13. Deposition of the anticorrosive coating 15 may take from about 20 min to about 60 min.

The insulating coating 13 may be composed of insulating polymers, such as polytetrafluoroethylene. When the insulating coating 13 is composed of polymers, the insulating coating 13 may be formed by chemical vapor deposition.

When the anticorrosive coating 15 is composed of TiON or CrON, oxygen and nitrogen can be fed into the vacuum chamber 31 as the reactive gases when forming the anticorrosive coating 15.

When the anticorrosive coating 15 is composed of TiCN or CrCN, nitrogen and a gas for offering carbon, such as methane or acetylene, can be fed into the vacuum chamber 31 as the reactive gases when forming the anticorrosive coating 15.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An article, comprising:
a substrate made of aluminum or aluminum alloy;
an insulating coating formed on the substrate, the insulating coating being electrically insulating; and
an anticorrosive coating formed on the insulating coating, the anticorrosive coating being a ceramic coating.

2. The article as claimed in claim 1, wherein the insulating coating is composed of an insulating ceramic material.

3. The article as claimed in claim 2, wherein the insulating ceramic material is silicon oxide or aluminum oxide.

4. The article as claimed in claim 2, wherein the insulating coating is formed by physical vapor deposition method.

5. The article as claimed in claim 1, wherein the insulating coating is composed of an insulating polymer.

6. The article as claimed in claim 5, wherein the insulating polymer is polytetrafluoroethylene.

7. The article as claimed in claim 5, wherein the insulating coating is formed by chemical vapor deposition method.

8. The article as claimed in claim 1, wherein the thickness of the insulating coating is about 2.0 μm to about 3.0 μm.

9. The article as claimed in claim 1, wherein the anticorrosive coating is composed of one ceramic material selected from the group consisting of TiN, TiON, TiCN, CrN, CrON, and CrCN.

10. The article as claimed in claim 1, wherein the anticorrosive coating is formed by physical vapor deposition.

11. A method for manufacturing an article, the method comprising the following steps of:
providing a substrate made of aluminum or aluminum alloy;
forming an insulating coating on the substrate, the insulating coating being electrically insulating; and
forming an anticorrosive coating on the insulating coating, the anticorrosive coating being an ceramic coating.

12. The method as claimed in claim 11, wherein the insulating coating is composed of silicon oxide or aluminum oxide.

13. The method as claimed in claim 12, wherein the insulating coating is formed by magnetron sputtering carried out under the following conditions: using targets made of silicon or aluminum; using oxygen at a flux of about 50 sccm to about 200 sccm as a reactive gas; using argon at a flux of about 150 sccm to about 300 sccm as a sputtering gas; applying a bias voltage in a range of about −50 V to about −300 V; evaporating the targets at a electric power of about 5 kW to about 13 kW; and under a temperature of about 50° C. to about 150° C.

14. The method as claimed in claim 13, wherein the magnetron sputtering of the insulating coating takes about 30 min to about 120 min.

15. The method as claimed in claim 12, wherein the insulating coating is composed of polytetrafluoroethylene.

16. The method as claimed in claim 15, wherein the insulating coating is formed by chemical vapor deposition.

17. The method as claimed in claim 12, wherein anticorrosive coating is composed of one ceramic material selected from the group consisting of TiN, TiON, TiCN, CrN, CrON, and CrCN.

18. The method as claimed in claim 17, wherein anticorrosive coating is formed by magnetron sputtering.
